(19) United States
(12) Patent Application Publication
(10) Pub. No.: US 2009/0114945 A1
(43) Pub. Date: May 7, 2009

(54) SPINTRONICS COMPONENTS WITHOUT NON-MAGNETIC INTERPLAYERS

(75) Inventors: Charles Gould, Wurzburg (DE); Georg Schmidt, Lindenflur (DE); Laurens W. Molenkamp, Wurzburg (DE)

Correspondence Address: BROWDY AND NEIMARK, P.L.L.C.;624 NINTH STREET, NW, SUITE 300, WASHINGTON, DC, 20001-5303, US

(73) Assignee: ETeCH AG, Schlieren (CH)

(21) Appl. No.: 12/066,742

(22) PCT Filed: Sep. 12, 2006
(86) PCT No.: PCT/CH06/00488

§ 371 Date: Aug. 4, 2008

Related U.S. Application Data
(60) Provisional application No. 60/716,075, filed on Sep. 13, 2005.

(51) Int. Cl. H01L 29/82

(52) U.S. Cl. 257/108; 257/E29.323

(57) ABSTRACT

A spintronics element comprises two ferromagnetic layers without a non-magnetic interlayer between them. The two ferromagnetic layers may be independently switched by various means such as but not limited to applying one or more external magnetic fields, and/or employing current induced switching, and/or applying optical spin-pumping.

### INTRODUCTION

In the production of electronic devices based upon the principles of spintronics, that is, using the location and sign of the spin of the electron rather than its charge as the pre-eminent factor under control, it is possible to include in such devices elements termed ‘spin valves’. Spin valves conventionally function by controlling the ability of one part of the valve, which forms part of an electrical circuit, to pass a spin-polarised electrical current, or not. This control is effected by other parts of the valve, which typically create and change magnetic fields in such a way as to allow or impede the spin-polarised current in the conducting part.

Such devices are known in ferromagnetic metallic systems, and involve two metallic ferromagnetic layers, the one controlling the magnetic state and thus the current flow in the other: such devices are currently commercially available as ‘giant magneto-resistive’ (GMR) elements in e.g., read heads employed with magnetic recording media. Analogous devices are also known and have been described in ferromagnetic semiconductor systems, and devices have also been made employing two ferromagnetic layers, where the first ferromagnetic layer is a metallic system and the second ferromagnetic layer is a non-metallic system. The effect can also be used in TMR (tunneling magneto-resistive) devices in spintronics.

However all such systems hitherto described actually consist of three layers, being the two magnetic layers separated by a non-magnetic ‘barrier’ layer. This barrier layer is essential in all such conventional systems, and serves to magnetically separate the two magnetic layers so that the interaction between the two magnetic layers is controllable, and so they do not act magnetically as one single layer. This barrier layer is typically composed of copper or similar in metallic GMR samples, an insulator such as AlOx, in metallic TMR structures, or an undoped semiconductor in Semiconductor TMR devices.

In the present disclosure, a novel effect has been observed, wherein two ferromagnetic materials, one metallic and one semiconductor, e.g., permalloy (NiFe, abbreviated: Py) and GaMnAs, directly deposited the one on the other, can be switched independently. This is a very interesting effect, and is believed to arise from the fact that the carriers in each material (electrons for NiFe, holes for GaMnAs) are different, and so bringing the two layers in direct contact does not lead to the two layers acting magnetically as a single layer.

It is also a commercially useful effect, as the non-magnetic interlayer previously thought necessary for such devices can be discarded: a two-layer device could be cheaper, faster, have higher efficiency, and have better signal to noise characteristics.

The charge transport for magnetoresistance phenomena, which gives a different resistance for such GMR/TMR devices depending on the magnetic orientation of the layers, as in a traditional GMR/TMR device, is dependant on the nature of the interface: for devices where the transport through this interface has an ohmic character, it would yield a GMR-type structure, whereas if a Schottky or p-n barrier is present at the interface, the device would act as a TMR.

Beyond the above, it is possible to set up in GaMnAs and other systems states in which the magnetizations of the two layers are neither parallel nor antiparallel, but which have more complex geometrical relationships; the simplest of these involve the two magnetizations remaining in the plane of the material layers but being offset by a certain angle, e.g., 90°, and the more complex of which involving magnetizations not in the plane or planes of the materials (one or both). Such more complex geometrical cases lead to operational behaviors where the system has three or more stable states, in comparison to the two stable states of hitherto known devices. These three or more states can be used directly for more complex computations than the essentially binary devices hitherto described. In addition, if the lower level is made of a material which exhibits tunneling anisotropic magnetoresistance (TAMR), then a TAMR component may also be present, potentially increasing the number of operable states even further.

### SHORT DESCRIPTION OF THE DRAWINGS

The invention will be illustrated in connection with a detailed description of embodiments shown in the drawings.

FIG. 1 shows the magnetization as a function of magnetic field of the bi-layer at 130 and 4.3K along one of the edges of samples of the invention

FIGS. 2 & 3 show magnetization curves at 4.3 K along each of the GaMnAs easy axis (100 and 001, with growth being along 001)

FIG. 4 shows the temperature dependence along one of the GaMnAs easy axis with curves roughly every 20K from 4.3K to 80K showing how the contribution of the GaMnAs dies away as it nears Tc

FIG. 5 shows a plot of the spontaneous magnetization of the sample along a GaMnAs easy axis as a function of temperature

FIG. 6 shows the perpendicular to plane magnetization showing that the out of plane moment is only some 10% of the in-plane moment

FIGS. 7 & 8 show the I-V of vertical transport measurements through the layer stack at zero applied magnetic field, for two separate devices

FIG. 9 shows the MR which results from applying a magnetic field

FIG. 10 shows a saturation plot

FIG. 11 shows a partial polar plot

FIGS. 12 & 13 show saturation phi scans at 60 and 80K.

### DETAILED DESCRIPTION OF PREFERRED EMBODIMENTS

We now provide a detailed technical description of one embodiment of the device in question. The sample consist two active layers deposited on a standard GaAs substrate and buffer. The first layer grown on the buffer is a thin film of GaMnAs grown by MBE. This is followed by a ˜2 nm layer of Py deposited in-situ onto the GaMnAs (i.e. the sample is transferred from the MBE growth chamber to the Py sputtering chamber under UHV conditions). The Py is deposited by magnetron sputtering, creating a magnetic anisotropy in the layer. The Py layer can especially be chosen between 1 and 5 and preferred between 1.5 and 2.5 nanometer thickness.

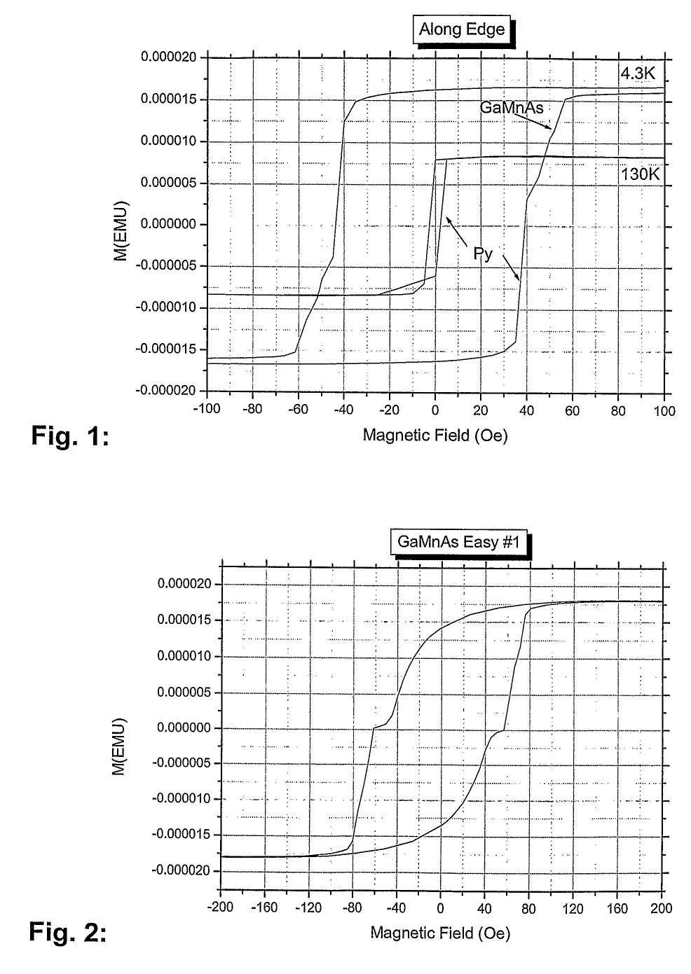

The bulk material is first characterized by SQUID magnetometry to confirm that the magnetization direction in each layer can be independently modified. This is put into evidence in FIGS. 1 through 6.

FIG. 1 shows the magnetization as a function of magnetic field of the bi-layer at 130 and 4.3K along one of the edges of the samples (i.e. a 110 crystal direction). Since 130K is well beyond the Curie temperature of our GaMnAs (˜70K) the only moment on seen on that curve is that of the Py, which is along an easy magnetic axis. At lower temperatures, we see an additional contribution from the GaMnAs in the form of a second switching event. (The asymmetric crossing in the 130K CoFe loop is an artifact of the measurement field resolution used for preliminary characterization, and not a real effect.)

FIGS. 2 and 3 show magnetization curves at 4.3 K along each of the GaMnAs easy axis (100 and 001, with growth being along 001). Both are similar, and in this configuration, the independent nature of the two layers becomes obvious. Since the Py is uniaxial, and the measurement is no longer along its easy axis, instead of a clear switching, we now see a gradual rotation of this layer, starting at around 100 Oe before zero, and ending some 40 Oe after zero. This is followed by the switching of the GaMnAs at ˜50 Oe, in a relatively abrupt switch as the measurement is along a GaMnAs easy axis. Note also the slight inflection in the GaMnAs switching near 75 Oe, more pronounced in FIG. 3 than FIG. 2. This is quite possible a “double step” switching of the GaMnAs layer, possibly suggesting that the measurement is slightly off the easy axis.

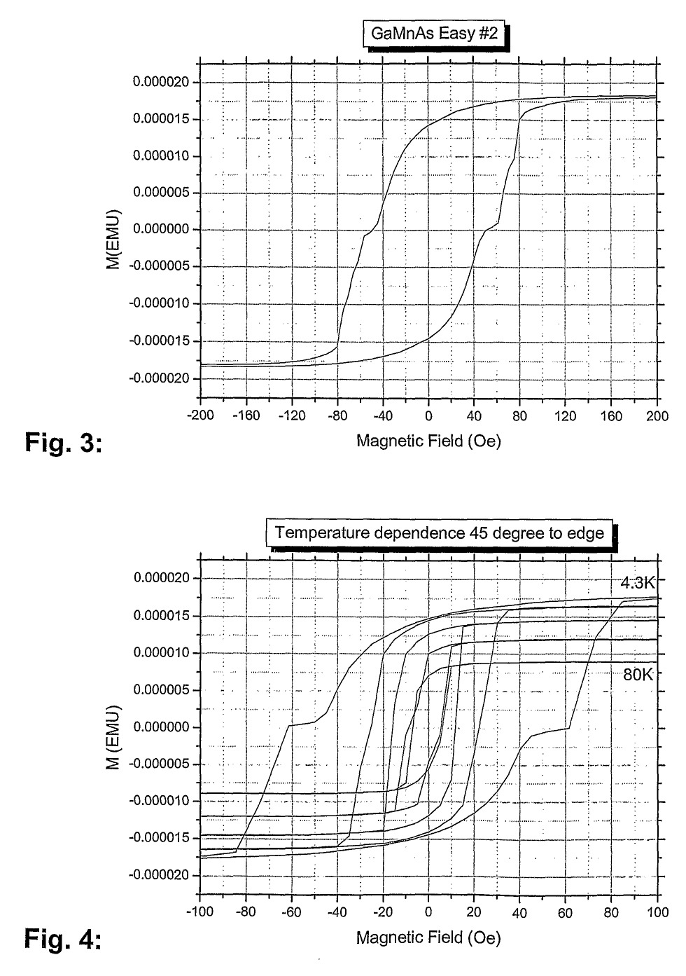

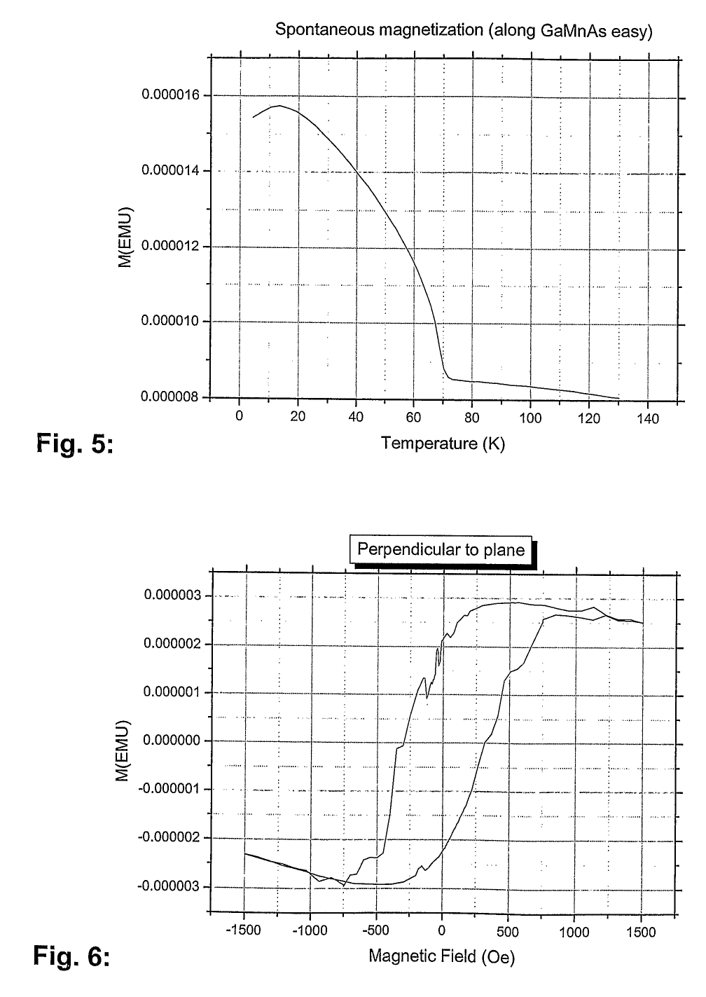

FIG. 4 shows the temperature dependence along one of the GaMnAs easy axis with curves roughly every 20K from 4.3K to 80K showing how the contribution of the GaMnAs dies away as it nears Tc. This is made clearer in FIG. 5, where the spontaneous magnetization of the sample along a GaMnAs easy axis is plotted as a function of temperature. The relatively constant contribution seen above 80K is the moment of the Py, which has little temperature dependence in this range. The contribution of the GaMnAs dies off as we approach its Tc, which this graph shows to be about 72K.

Finally, FIG. 6 shows the perpendicular to plane magnetization showing that the out of plane moment is only some 10% of the in-plane moment (Note the y-scale), indicating that as expected, our sample has strong in-plane anisotropy.

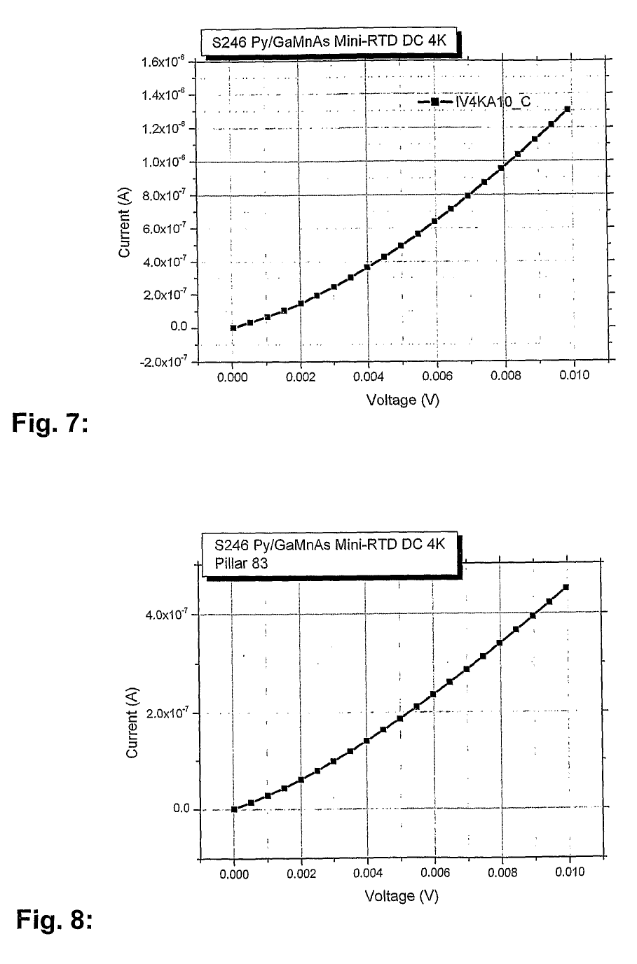

We now turn to a transport characterization of the sample, which is put into evidence in FIGS. 7 through 13.

FIGS. 7 and 8 show the I-V of vertical transport measurements through the layer stack at zero applied magnetic field, for two separate devices. The first has non-linear behavior, whereas the second is linear. Despite the difference in resistance in these pillars, both devices exhibit similar magnetoresistance perhaps suggesting this geometry may be, under proper interface optimization, operable in both ohmic (GMR) and tunneling (TMR, TAMR) modes.

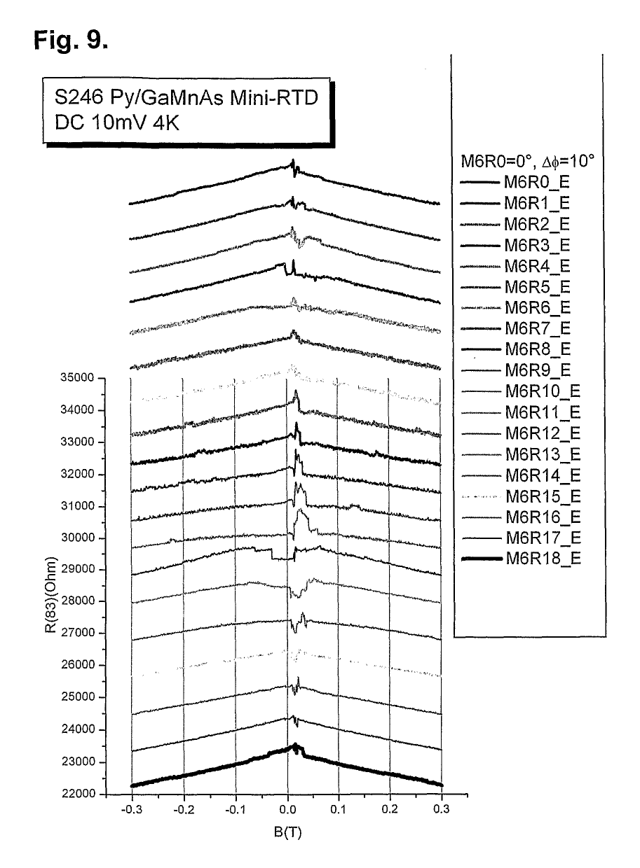

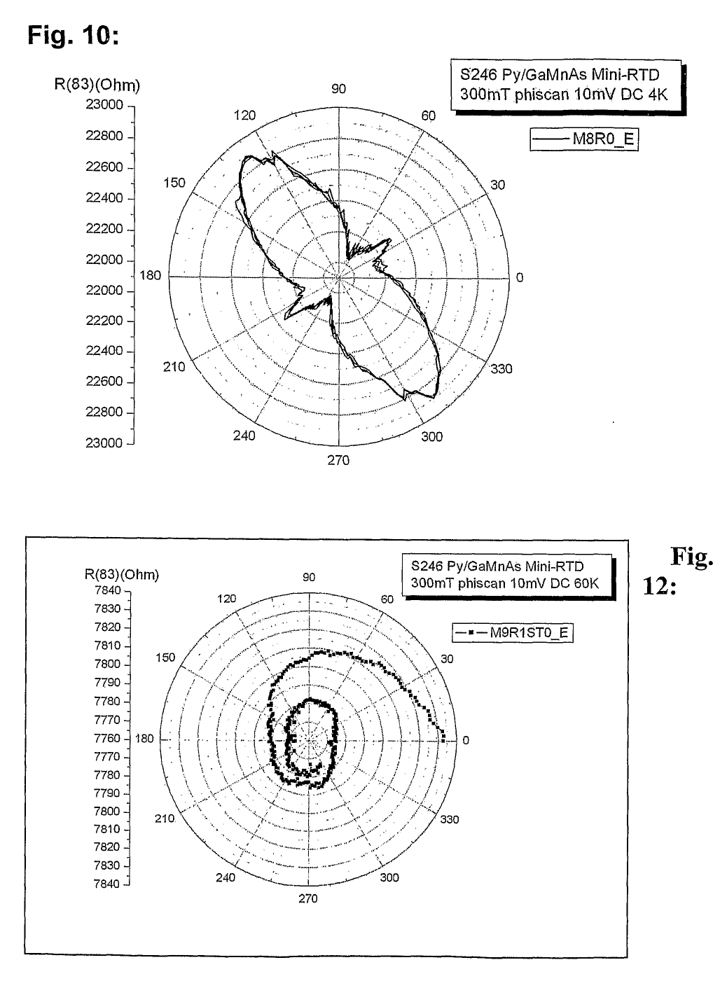

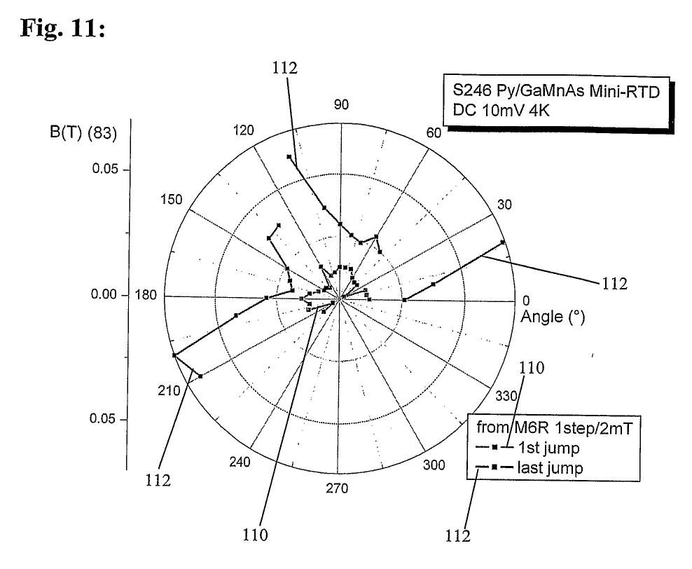

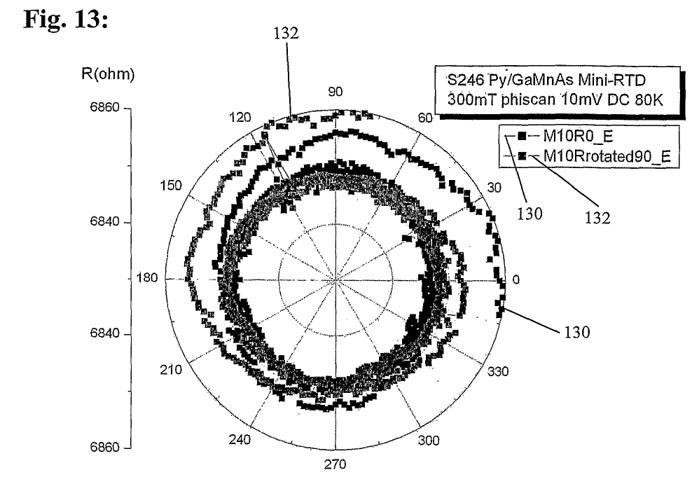

FIG. 9 shows the MR which results from applying a magnetic field. The field is applied in the plane of the sample, and along various angles. As can be seen, the sample shows significant MR at all angles, with a rich evolution of the behavior as a function of angle. From these plots, the resistance of the device can be seen to be a consequence to the direction of magnetization (both relative, and absolute) in the two layers. Part of the signals is undoubtedly due to the TAMR effect in the GaMnAs, as suggested by the saturation plot of FIG. 10, and the partial polar plot of FIG. 11, but additional contributions remain which are inconsistent with pure TAMR in GaMnAs, and forcibly result from either the contribution of the Py, or a contribution from an interplay between the two layers.

It is also interesting to note that preliminary measurements suggest that the part of the MR which comes from the Py layer may survive past the Curie temperature of GaMnAs. FIGS. 12 and 13 show saturation phi scans at 60 and 80K. The outward arm of the spiral comes from long term temperature drift from a poorly controlled temperature stability in these preliminary measurements, but the eccentricity of the inner circle, seen clearly in FIG. 12, is real and reproducible. It is also still visible, thought not as obvious, in the 80K data of FIG. 13, where the data is plotted twice, in separate colors, with one of the plots rotated by 90 degrees, to make the eccentricity more evident.

This survival of part of the effect above the Tc of the GaMnAs, suggest that it is related to the Py, either because of an intrinsic property of this layer, or by the action of the Py on the Mn atoms in the semiconductor and may represent a way of pushing TAMR above room temperature.

The legend on the right of FIG. 9 refers to the graphs on the left of FIG. 9. The sequence of the legends from the top to the bottom is according to the sequence of the graphs from the top to the bottom. As an example: the legend for M6RO_E relates the first graph seen from the top, the legend M6R1_E relates to the second graph seen from the top and so on. The legend M6R18_E refers to the last graph, which is the graph at the bottom.

Reference numeral 110 in FIG. 11 relates to the 1^{st} jump, as indicated in the legend of FIG. 11 and reference numeral 112 relates to the last jump.

Reference numeral 130 in FIG. 13 relates to the M10R0_E graph and reference numeral 132 relates to the M10Rrotated90_E graph.

1-18. (canceled)

19. Spintronics element comprising:
two ferromagnetic layers without a non-magnetic interlayer between them, and
ferromagnetic layer switching elements adapted to switch ferromagnetic layers,
wherein the ferromagnetic layer switching elements are adapted to switch the two ferromagnetic layers independently one from the other.

20. Spintronics element according to claim 19, wherein the ferromagnetic layer switching elements are chosen from the group of elements applying one or more external magnetic fields, elements employing current induced switching, and elements applying optical spin-pumping.

21. Spintronics element according to claim 19, wherein the magnetizations of the two ferromagnetic layers are both in the plane of the layer to which each relates, and are essentially controllable so as to be parallel or anti-parallel to each other.

22. Spintronics element according to claim 19, wherein at least the magnetization of one of the two ferromagnetic layers is in the plane of the magnetic layer to which it relates, and is essentially controllable so as to have at least two stable magnetic configurations.

23. Spintronics element according to claim 19, wherein the ferromagnetic layers comprise at least two different stable magnetic states which directly correlate to different states of electrical resistance in one or both layers or the element as a whole.

24. Spintronics element according to claim 19, wherein the ferromagnetic layers are of different material characters, wherein one ferromagnetic layer is essentially metallic and wherein the other ferromagnetic layer is essentially non-metallic.

25. Spintronics element according to claim 24, wherein the essentially non-metallic ferromagnetic layer is a semiconductor.

26. Spintronics element according to claim 19, wherein the ferromagnetic layers are of similar or identical material character, wherein the boundary between the two ferromagnetic layers is defined by a change in material and/or magnetic anisotropy.

27. Spintronics element according to claim 19, wherein the boundary between the two ferromagnetic layers is created by the two ferromagnetic layers being formed one above the other.

28. Spintronics element according to claim 19, wherein the boundary between the two ferromagnetic layers is created by the two ferromagnetic layers being formed adjacent to each other.

29. Spintronics element according to claim 28, wherein the two ferromagnetic layers are provided on a common substrate.

30. Spintronics elements according to claim 19, wherein one ferromagnetic layer is a ferromagnetic semiconductor and wherein a ferromagnetic over layer is provided extending the magnetic properties of the semiconductor to higher temperatures.

31. Spintronics element according to claim 19, wherein the two ferromagnetic layers are deposited one on the other, wherein one layer is a ferromagnetic metallic layer and the other layer is a ferromagnetic semiconductor layer, to be switched independently.

32. Spintronics element according to claim 31, wherein the ferromagnetic metallic layer is permalloy, especially NiFe (abbreviated: Py) and the ferromagnetic semiconductor layer is GaMnAs.

33. Spintronics element according to claim 32, wherein the ferromagnetic metallic layer is NiFe (abbreviated: Py).

34. Spintronics element according to claim 19, wherein the ferromagnetic semiconductor layer is a thin film, especially MBE grown on the buffer of a GaAs substrate, and wherein the ferromagnetic metallic layer is a 1 to 5 nanometer, especially 1.5 to 2.5 nanometer, Py layer.

35. Spin-valve device including a spintronics element comprising:
two ferromagnetic layers without a non-magnetic interlayer between them, and
ferromagnetic layer switching elements adapted to switch ferromagnetic layers,
wherein the ferromagnetic layer switching elements are adapted to switch the two ferromagnetic layers independently one from the other.

36. GMR, TMR or TAMR device including a spintronics element comprising:
two ferromagnetic layers without a non-magnetic interlayer between them, and
ferromagnetic layer switching elements adapted to switch ferromagnetic layers,
wherein the ferromagnetic layer switching elements are adapted to switch the two ferromagnetic layers independently one from the other.
